(19) United States
(12) Patent Application Publication
(10) Pub. No.: US 2012/0247822 A1
(43) Pub. Date: Oct. 4, 2012

(54) CORELESS LAYER LAMINATED CHIP CARRIER HAVING SYSTEM IN PACKAGE STRUCTURE

(75) Inventors: James W. Fuller, JR., Endicott, NY (US); Jeffrey Knight, Endwell, NY (US); Voya R. Markovich, Endwell, NY (US); Kostas I. Papathomas, Endicott, NY (US)

(73) Assignee: Endicott Interconnect Technologies, Inc., Endicott, NY (US)

(21) Appl. No.: 13/073,307

(22) Filed: Mar. 28, 2011

(51) Int. Cl. H05K 1/16; H05K 3/00

(52) U.S. Cl. 174/260; 29/829

(57) ABSTRACT

A substrate for use in a laminated chip carrier (LCC) and a system in package (SiP) device having a coreless buildup layer and at least one metal and at least one dielectric layer. The coreless buildup dielectric layers can include thermoset and thermoplastic resin.

### FIELD OF THE INVENTION

The present invention relates to laminated chip carrier (LCC) manufacturing and preparation and, more specifically, to a structure having an LCC that is built up utilizing thermoset resin or thermoplastics.

### BACKGROUND OF THE INVENTION

A common procedure in the circuit card manufacturing process involves laminating multiple cores together. However, generally the cores are not electrically connected via to via during lamination. For example, one method involves first electrically connecting the cores using conductive pads. After lamination, a hole is drilled through the conductive pads and electroplated with conductive material such as copper to form the via.

An alternative solution uses conductive adhesive in a lamination process. The conductive adhesive is placed on a via and electrically connects the vias when the cores are laminated together. However, conductive adhesives contain plate-like structures greater than 0.5 mils in size. These plates tend to clog at the top of the holes. Therefore, the adhesives cannot be used effectively with thicker cores and smaller vias. Additionally, conductive adhesives require a precious metal for good connections, making finished products more expensive. Finally, a substantial number of manufacturing sites are not equipped to handle conductive adhesives. Consequently, significant costs may be required to modify current manufacturing sites to use conductive adhesives.

As a result, there exists a need for a structure and method of attaching cores having vias with conductive surfaces without using a conductive material for the joining process such as is currently used.

### DISCUSSION OF RELATED ART

U.S. Pat. No. 6,659,355, by Fischer, et al. granted Dec. 9, 2003, for METHOD FOR PRODUCING A MULTI-LAYER CHIP CARD discloses a method for producing a chip card provided with a plastic card body. The card body has several layers, an integrated circuit that is arranged in a chip module, and at least two additional electronic components for producing an interactive chip card. The components and the chip module are connected to each other by means of strip conductors arranged on a carrier layer and align with metallic contact surfaces connected to the conductors. Several cover layers are mounted on the conductor carrier layer and are provided with recesses corresponding to the metallic contact surfaces. The individual card layers of the plastic card body are laminated and as a result the metallic contact surfaces are pushed upwards within the recesses of the cover layers to a point where the contact surfaces rest on a cover layer or a thickness compensation layer.

U.S. Pat. No. 7,033,517 by Fan, et al. granted Apr. 25, 2006 for METHOD OF FABRICATING A LEADLESS PLASTIC CHIP CARRIER discloses a leadless plastic chip carrier fabricated by partially etching at least a first surface of a leadframe strip to partially define a die attach pad. A plurality of contact pads is disposed around the die attach pad, and a plurality of bond fingers is intermediate the die attach pad and the contact pads. A metal strip is laminated to the first surface of the leadframe strip. A second surface of the leadframe strip is selectively etched such that portions of the leadframe strip are removed to define a remainder of the die attach pad, the plurality of contact pads, the plurality of bond fingers, and circuitry between the bond fingers and contact pads. A semiconductor die is mounted to the die attach pad and wire bonds connect the semiconductor die to the bond fingers. The second surface of the leadframe strip, the semiconductor die, and the wire bonds are encapsulated in a molding material. The metal strip is removed from the first surface of the leadframe strip and the leadless plastic chip carrier is singulated from a remainder of the leadframe strip.

U.S. Pat. No. 7,550,316 by Kang, et al. granted Jun. 23, 2009 for BOARD ON CHIP PACKAGE AND MANUFACTURING METHOD THEREOF discloses a manufacturing method for a board on chip package. The method can comprise: laminating a dry film on a carrier film, one side of which is laminated by a thin metal film; patterning the dry film in accordance with a circuit wire through a light exposure and developing process, and forming a solder ball pad and a circuit wire; removing the dry film; laminating an upper photo solder resist excluding a portion where the solder ball pad is formed; etching the thin metal film formed on a portion where the upper photo solder resist is not laminated; mounting a semiconductor chip on the solder ball pad by a flip chip bonding; molding the semiconductor chip with a passivation material; removing the carrier film and the thin metal film; and laminating a lower photo solder resist under the solder ball pad. The board on chip package and the manufacturing method thereof according to the present invention can design a high-density circuit since a circuit pattern is formed using a seed layer.

### SUMMARY OF THE INVENTION

According to the present invention, there is provided a method and structure of attaching a plurality of coreless card structures. A substrate for use in a laminated chip carrier/SiP has a coreless buildup layer.

A first aspect of the invention is directed to having coreless buildup layers consisting of thermoset resin. Each or alternate buildup layers are partially advanced to process circuitization and are subsequently fully cured during final lamination process. Example of buildup layers are: resin coated Cu such as Driclad®, and PPE.

A second aspect of the invention is directed to a method having coreless buildup layers consisting of thermoplastics. Each buildup layer is circuitized and subsequently laminated to form the final structure. Examples of buildup layers are: Polyimide, LCP or Teflon® based materials.

A third aspect of the invention is directed to a structure having coreless buildup layers consisting of thermoset and/or thermoplastic resin. Here the thermoset buildup layers are partially advanced to process circuitization and are subsequently fully cured during a final lamination process.

A fourth aspect of the invention is directed to a method having coreless buildup layers consisting of thermoset and/or thermoplastic resin. Here thermoset buildup layers are fully cured and circuitized. Thermoplastic may melt and form bonding among the buildups.

A fifth aspect of this invention is directed to a structure utilizing a combination of high performance computing (HPC) and HPC Z-interconnect building blocks.

A sixth aspect of the invention is removing the need for Thermount or other core materials to provide rigidity to fabricate coreless structures.

It is an object of this invention to use structures that provide a low cost, high performance, and easily manufactured solution.

It is another object of this invention to allow replacing of multi-chip modules and multi-component modules (MCM's) with a land grid array (LGA) connection to the back panel of a computing device.

### BRIEF DESCRIPTION OF THE DRAWINGS

These and other features and advantages of this invention will be more readily understood from the following detailed description of the various aspects of the invention taken in conjunction with the accompanying drawings in which:

FIGS. 1 through 6 show a longitudinal, sectional view, somewhat diagrammatic, of the steps to form a coreless member.

It is noted that the drawings of the invention are not to scale. The drawings are merely schematic representations, not intended to portray specific parameters of the invention. The drawings are intended to depict only typical embodiments of the invention, and therefore should not be considered as limiting the scope of the invention. In the drawings, like numbering represents like elements among the drawings. In other words, for the sake of clarity and brevity, like elements and components of each embodiment bear the same designations throughout the description.

### DESCRIPTION OF THE PREFERRED EMBODIMENT

In the invention, a method and structure are provided for electrically joining a plurality of layers using thermoset resin and/or thermoplastic creating a rigid substrate for use in a laminated chip carrier (LCC) system in package (SiP), consisting of a coreless buildup layer with an upper and a lower surface and circuitized metal layers containing plated through holes, at least one of the plated through holes being a blind via electrically connected to the layer below and covered by a solder bump at the exposed surface, and at least one additional layer of dielectric material placed on each of side of the circuitized layers.

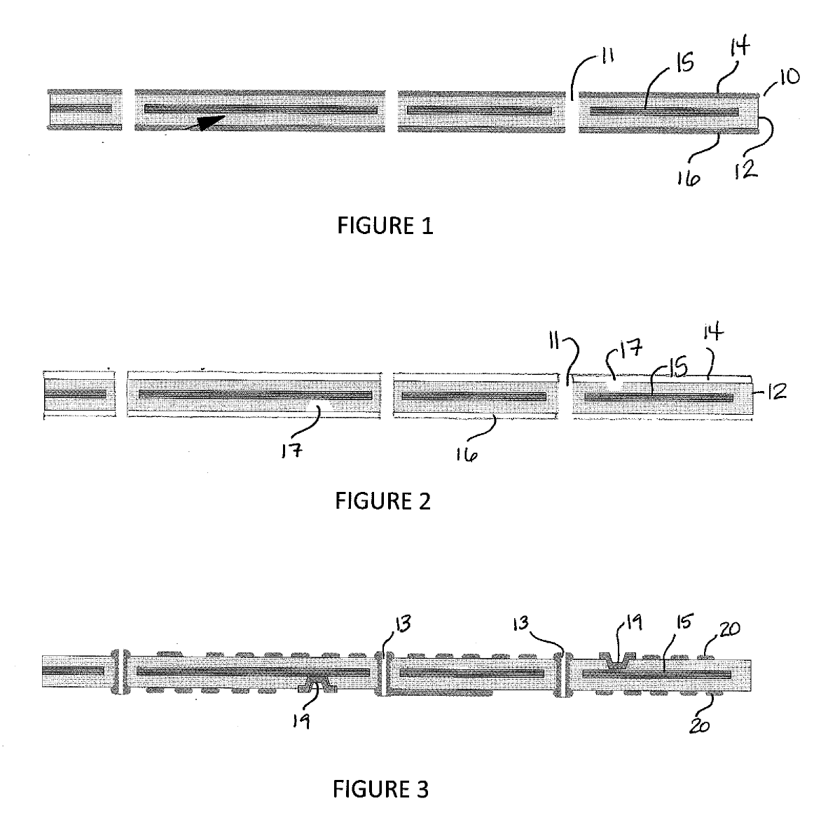

Referring now to the drawings and, for the present, to FIGS. 1 through 6, the successive steps are shown to form a coreless member 10 for use in laminating to another core member to form a printed wiring board according to one embodiment of the invention. As can be seen in FIG. 1, coreless member 10 includes a dielectric substrate 12 and contains an embedded capacitance layer 15. The embedded capacitance layer at numeral 15 may also be copper-invar-copper (CIC) or copper foil. The embodiment described in this detailed description utilizes a capacitance layer. The dielectric substrates and layers referenced herein can be low loss capacitance or high dielectric constant layers. It is dependent upon the final needs of the circuit designer as to what material is chosen. Low loss signifies any dielectric and, specifically for these applications, a dielectric layer or material that has a dielectric permittivity less than 0.001. High dielectric may encompass dielectric layers having dielectric constants greater than the 4.5.

Through holes 11 are formed in the structure of the coreless member 10 by any number of techniques well known in the art. Dielectric substrate 12 can be any conventional dielectric, such as FR4 (a glass reinforced epoxy), polyimide, polytetrafluoroethylene (PTFE) or other suitable, well-known dielectric. Layers of metal coatings 14 and 16 are disposed on opposite faces of dielectric. In the embodiment shown in FIGS. 1 through 6, the metal coatings 14 and 16 preferably are copper and, typically, the layer is either one-half oz. copper (17.5 μm thick), one oz. copper (35 μm thick) or two oz. copper (70 μm thick). However, other thicknesses of copper coatings can be used.

As shown in FIG. 2, the dielectric substrate 12 has blind vias 17 mechanically or laser drilled down to the capacitance layer 15 enclosed therein in a predetermined pattern.

As shown in FIG. 3, figure does not show trace 18 but shows 20 top and bottom preferably copper layers 14 and 16 are patterned to form circuit traces 18 and 20, respectively. Any conventional patterning process (e.g., by using a photoresist, exposing, developing and etching the exposed areas and then stripping the photoresist) can be used. This process creates circuit traces 18 and 20 that allow for electrical signal movement across the layer of dielectric 15. Through holes 11 and blind vias 17 are plated with copper, thereby creating plated through holes 13 and plated blind vias 19. The plated through holes 13 and plated blind vias 19 allow for (normally not used but try replacing with “electrical connectivity in the out of plane or z direction” electron movement in the z direction, perpendicular to the plane of dielectric 15, and have electrical connections to the capacitance layer 15 in the case of the blind vias 19.

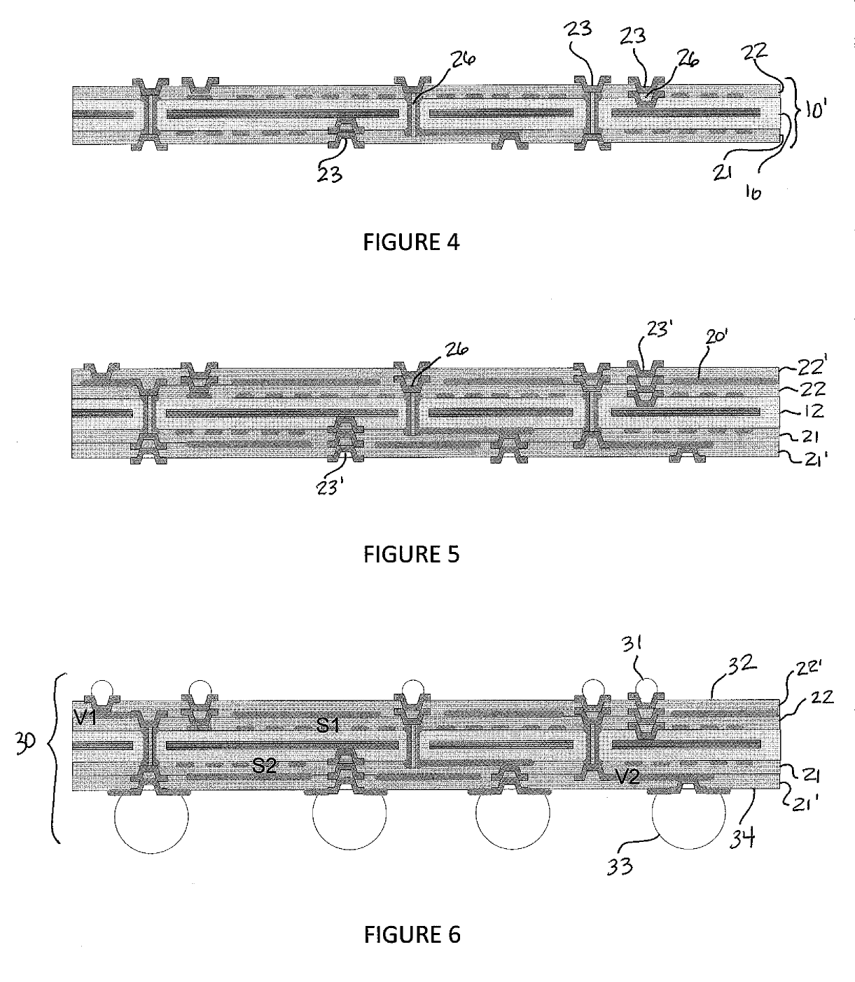

As shown in FIG. 4, a second layer 21 and 22 of dielectric material is disposed on the upper and lower surface, respectively, of the base coreless member 10, and contains plated through holes 23 (the blind vias are shown in the figure as 23 as well need to be corrected) and circuit traces 20 to allow electrical connectivity between the various layers that make up the coreless buildup assembly 30 (FIG. 6). Into the plated through holes 13 and plated through holes 23 (plated through hole 13 and 23 is the same so statement needs to be modified is deposited an electrically conductive material 26. The filling of these plated through holes 13 can be performed by screening, stenciling, flood coating, doctor blading, immersing or injecting. Various types of conductive material may be used. A preferred conductive polymer material is a conductive epoxy sold by National Starch and Chemical Company under the trademark “Ablebond 8175,” which is a silver filled thermosetting epoxy. Alternatively, a solder paste of tin lead, tin lead silver, tin silver copper, tin silver copper antimony or tin bismuth, commercially available, can be used and heated to reflow.

As shown in FIG. 5, consecutive layers 21′ and 22′ of dielectric material are disposed on the upper and lower surface, respectively, of the base coreless assembly 10′, and contain plated through holes 23′ (23″ are not plated through holes but plated blind vias and in this cased are stacked blind vias and circuit traces 20′ to allow electron movement between the various layers that make up the coreless buildup assembly 30 (FIG. 6). Into the plated through holes 23 is deposited an electrically conductive material 26. The filling of these plated through holes 23 can also be performed by screening, stenciling, flood coating, doctor blading, immersing or injecting. This consecutive layering is limited only by manufacturing capability.

FIG. 6 shows a fully laminated coreless buildup assembly 30 with solder bumps 31 on the upper surface 32 of coreless buildup assembly 30, and solder balls 33 on the lower surface 34 of coreless buildup assembly 30 in a land grid array pattern. Of course solder balls 33 may also be formed on the upper surface 32 of assembly and solder bumps 31 may also be formed on the lower surface 34 of the coreless buildup assembly 30. The solder bumps and BGAs can be either lead or lead free containing Al.

Both types of connections either towards the device or the circuit board can be made with materials which are available in many different alloys for differing applications. In electronics assembly, the eutectic alloy of 63% tin and 37% lead (or 60/40, which is almost identical in performance to the eutectic) has been the alloy of choice.

Common solder alloys are mixtures of tin and lead, respectively:
63/37: melts at 183 C (361 F) (eutectic: the only mixture that melts at a point, instead of over a range)
60/40: melts between 183-190° C. (361-374° F.)
50/50: melts between 185-215° C. (365-419° F.)

Since other modifications and changes to the coreless layer buildup will be apparent to those skilled in the art, the invention is not considered limited to the description above for purposes of disclosure, and covers all changes and modifications which do not constitute departures from the true spirit and scope of this invention.

Having thus described the invention, what is desired to be protected by Letters Patent is presented in the subsequently appended claims.

What is claimed is:

1. A substantially rigid substrate for use in a laminated chip carrier (LCC) system in package (SiP) comprising:
a) a coreless buildup layer having an upper surface and a lower surface;
b) first and second circuitized metal layers having a plurality of plated through holes, at least one of said plated through holes being a blind via electrically connected to said coreless buildup layer and covered by a solder bump at the exposed surface thereof, disposed on said upper surface and said lower surface, respectively, of said coreless capacitance buildup layer; and
c) at least one additional layer of material disposed on each of said first and said second circuitized layers, said at least one additional layer comprising dielectric material.

2. The substantially rigid substrate as per claim 1, wherein said coreless buildup layer comprises at least one from the group: capacitance, copper-invar-copper (CIC), and copper foil.

3. The substantially rigid substrate as per claim 1, wherein said coreless buildup layer comprises a thermoset resin.

4. The substantially rigid substrate as per claim 1, wherein said coreless buildup layer comprises a thermoplastic resin.

5. The substantially rigid substrate as per claim 3, wherein said coreless buildup layer comprises alternate layers of partially cured and fully cured resin.

6. The substantially rigid substrate as per claim 1, further comprising:
c) a second metal layer disposed on the top and bottom of said substantially rigid substrate, respectively; and
d) a first joining layer of dielectric disposed between each of said first and said second metal layers, respectively.

7. The substantially rigid substrate as per claim 6, wherein said first joining layers of dielectric comprise low loss capacitance material.

8. The substantially rigid substrate as per claim 6, wherein said first joining layers of dielectric comprises at least one from the group: partially cured thermoset resin and thermoplastic.

9. The substantially rigid substrate as per claim 6, wherein said first joining layers of dielectric comprise at least one from the group: high dielectric constant and low loss capacitance layer.

10. The substantially rigid substrate as per claim 6, wherein said first and said second metal layers comprise resistor foil laminated and circuitized on said joining layer of dielectric, said joining layer of dielectric comprising at least one from the group: at least partially cured thermoset and thermoplastic resin dielectric layer.

11. The substantially rigid substrate as per claim 10, wherein said laminated and circuitized resistor foil comprises at least one from the group: high dielectric constant and low loss capacitance layer.

12. The substantially rigid substrate as per claim 6, further comprising;
e) a third metal layer disposed on the top and bottom of said substantially rigid substrate, respectively.

13. The substantially rigid substrate as per claim 12, further comprising:
f) a second joining layer of dielectric disposed between each of said second and said third metal layers, respectively.

14. The substantially rigid substrate as per claim 13, wherein said second joining layer of dielectric comprises capacitance material.

15. The substantially rigid substrate as per claim 12, wherein said first and said second and said third metal layers comprise at least one from the group: signal, power, and ground.

16. A method for fabricating a substantially rigid substrate for use in a laminated chip carrier, the steps comprising:
a) providing a coreless buildup layer; and
b) disposing a first metal layer on each surface of said coreless buildup layer.

17. The method as per claim 16, wherein said coreless buildup layer comprises alternate layers of partially cured and fully cured resin.

18. The method as per claim 16, the steps further comprising:
c) providing a second metal layer above and below said coreless buildup layer, respectively; and
d) disposing a first joining layer of dielectric between each of said first and said second metal layers, respectively.

19. The method as per claim 18, wherein said first joining layers of dielectric comprise low loss capacitance material.

20. The method as per claim 18, wherein said first joining layers of dielectric comprise at least one from the group: partially cured thermoset resin and thermoplastic.

21. The method as per claim 18, wherein said first joining layers of dielectric comprise at least one from the group: high dielectric constant and low loss capacitance layer.

22. The method as per claim 18, wherein said first and said second metal layers comprise resistor foil that is laminated and circuitized on at least one from the group: at least partially cured thermoset and thermoplastic resin.
